(19) United States
(12) Patent Application Publication
(10) Pub. No.: US 2024/0389422 A1
(43) Pub. Date: Nov. 21, 2024

(54) DISPLAY PANEL AND DISPLAY DEVICE

(71) Applicants: Wuhan Tianma Micro-clectronics Co., Ltd., Wuhan (CN); Wuhan Tianma Micro-Electronics Co., Ltd .Shanghai Branch, Shanghai (CN)

(72) Inventors: ZHUAN GAO, Wuhan (CN); Peng ZHANG, Wuhan (CN)

(21) Appl. No.: 18/652,166

(22) Filed: May 1, 2024

(30) Foreign Application Priority Data
May 18, 2023 (CN) 202310575444.7

(51) Int. Cl. H10K 59/35; H10K 59/40; H10K 102/00

(52) U.S. Cl. CPC H10K 59/353; H10K 59/40; H10K 2102/351

(57) ABSTRACT

A display panel and a display device are provided. The display panel includes a first base substrate and a second base substrate oppositely arranged; and a support pillar disposed between the first base substrate and the second base substrate. The first base substrate includes a first substrate and pixel openings disposed on a side of the first substrate facing the second base substrate; the second base substrate includes a second substrate and a first insulation layer disposed on a side of the second substrate facing the first base substrate; the first insulation layer includes a first insulation portion overlapping with the support pillar in a first direction and including a first edge; an orthographic projection of the first edge on the first substrate is located outside an orthographic projection of the pixel opening on the first substrate; the two projections have a first preset distance D; and D>0.

### CROSS-REFERENCE TO RELATED APPLICATION

This application claims the priority of Chinese Patent Application No. 202310575444.7, filed on May 18, 2023, the content of which is incorporated by reference in its entirety.

### TECHNICAL FIELD

The present disclosure generally relates to the field of display technologies and, more particularly, relates to a display panel and a display device.

### BACKGROUND

From the era of cathode ray tube (CRT) to the era of liquid crystal display (LCD), and now to the era of organic light-emitting diode (OLED) and the era of light-emitting diode display, the display industry has been constantly developed. The display industry has been involved, from traditional mobile phones, tablets, TVs, and PCs, to current smart wearable devices, VR, car displays and other electronic devices that are inseparable from the display technology.

With the development of the display technologies, users have higher and higher requirements for display products, how to reduce the signal coupling problem in the display panel has become one of the urgent to-be-solved technical problems at this stage. The present disclosed display panels and display devices are direct to solve one or more problems set forth above and other problems in the arts.

### SUMMARY

One aspect of the present disclosure provides a display panel. The display panel includes a first base substrate and a second base substrate oppositely arranged; and a support pillar disposed between the first base substrate and the second base substrate. The first base substrate includes a first substrate and a plurality of pixel openings disposed on a side of the first substrate facing the second base substrate; the second base substrate includes a second substrate and a first insulation layer disposed on a side of the second substrate facing the first base substrate; the first insulation layer includes a first insulation portion; in a first direction, the first insulation portion overlaps with the supporting pillar; the first direction is perpendicular to a plane where the first substrate is located; the first insulation portion includes a first edge; an orthographic projection of the first edge on the first substrate is located outside an orthographic projection of the pixel opening on the first substrate; the orthographic projection of the first edge on the first substrate and the orthographic projection of the pixel opening on the first substrate have a first preset distance D; and D>0.

Another aspect of the present disclosure provides a display device. The display device includes a display panel. The display panel includes a first base substrate and a second base substrate oppositely arranged; and a support pillar disposed between the first base substrate and the second base substrate. The first base substrate includes a first substrate and a plurality of pixel openings disposed on a side of the first substrate facing the second base substrate; the second base substrate includes a second substrate and a first insulation layer disposed on a side of the second substrate facing the first base substrate; the first insulation layer includes a first insulation portion; in a first direction, the first insulation portion overlaps with the supporting pillar; the first direction is perpendicular to a plane where the first substrate is located; the first insulation portion includes a first edge; an orthographic projection of the first edge on the first substrate is located outside an orthographic projection of the pixel opening on the first substrate; the orthographic projection of the first edge on the first substrate and the orthographic projection of the pixel opening on the first substrate have a first preset distance D; and D>0.

Other aspects of the present disclosure can be understood by those skilled in the art in light of the description, the claims, and the drawings of the present disclosure.

### BRIEF DESCRIPTION OF THE DRAWINGS

To illustrate the technical solutions in the embodiments of the present disclosure more clearly, the following briefly introduces the accompanying drawings used in the description of the embodiments. Obviously, the accompanying drawings in the following description are only some embodiments of the present disclosure, for those of ordinary skill in the art, other drawings may also be obtained from these drawings without creative effort.

FIG. 1 illustrates a top view of an exemplary display panel according to various disclosed embodiments of the present disclosure;

FIG. 2 illustrates a layout of pixels of an exemplary display panel according to various disclosed embodiments of the present disclosure;

FIG. 3 is an exemplary AA-sectional view in FIG. 2;

FIG. 4 is another exemplary AA-sectional view in FIG. 2;

FIG. 5 is another exemplary AA-sectional view in FIG. 2;

FIG. 6 is an exemplary layer structure when a first insulation portion extends to a pixel opening according to various disclosed embodiments of the present disclosure;

FIG. 7 is another exemplary AA-sectional view in FIG. 2;

FIG. 8 is another exemplary AA-sectional view in FIG. 2;

FIG. 9 is an exemplary relative positional relationship between a support pillar and a first insulation portion according to various disclosed embodiments of the present disclosure;

FIG. 10 is another exemplary relative positional relationship between a support pillar and a first insulation member according to various disclosed embodiments of the present disclosure;

FIG. 11 is an exemplary relative positional relationship between a support pillar and a first insulation portion according to various disclosed embodiments of the present disclosure;

FIG. 12 is an exemplary relative positional relationship between a pixel opening in the display panel and an adjacent first insulation portion according to various disclosed embodiments of the present disclosure;

FIG. 13 is an exemplary distribution of a pixel opening in the display panel and a support pillar according to various disclosed embodiments of the present disclosure;

FIG. 14 is another exemplary distribution of a pixel opening in the display panel and a support pillar according to various disclosed embodiments of the present disclosure;

FIG. 15 is another exemplary distribution of a pixel opening in the display panel and a support pillar according to various disclosed embodiments of the present disclosure;

FIG. 16 is another exemplary distribution of a first insulation portion and a support pillar according to various disclosed embodiments of the present disclosure;

FIG. 17 is another exemplary positional relationship between a pixel opening and an adjacent first insulation portion according to various disclosed embodiments of the present disclosure;

FIG. 18 is an exemplary BB-sectional view in FIG. 17;

FIG. 19 is another exemplary AA-sectional view in FIG. 2;

FIG. 20 is another exemplary AA-sectional view in FIG. 2;

FIG. 21 is an exemplary AA-sectional view when the display panel in FIG. 2 is disposed with a touch layer;

FIG. 22 is another exemplary AA-sectional view when the display panel in FIG. 2 is disposed with a touch layer;

FIG. 23 is another exemplary AA-sectional view when the display panel in FIG. 2 is disposed with a touch layer;

FIG. 24 is another exemplary AA-sectional view when the display panel in FIG. 2 is disposed with a touch layer; and

FIG. 25 illustrates an exemplary display device according to various disclosed embodiments of the present disclosure.

### DETAILED DESCRIPTION

Various exemplary embodiments of the present disclosure will now be described in detail with reference to the accompanying drawings. It should be noted that the relative arrangements of components and steps, numerical expressions and numerical values set forth in these embodiments do not limit the scope of the present disclosure unless specifically stated otherwise.

The following description of at least one exemplary embodiment is merely illustrative in nature and in no way taken as limiting the disclosure, its application or uses.

Techniques, methods and devices known to those of ordinary skill in the relevant art may not be discussed in detail, but where appropriate, such techniques, methods and devices should be considered as parts of the description.

In all examples shown and discussed herein, any specific values should be construed as exemplary only, and not as limitations. Therefore, other instances of the exemplary embodiment may have different values.

It will be apparent to those skilled in the art that various modifications and variations can be made in the present disclosure without departing from the spirit or scope of the disclosure. Therefore, the present disclosure is intended to cover the modifications and variations of the present disclosure falling within the scope of the corresponding claims (technical solutions to be protected) and their equivalents. It should be noted that, the implementation manners provided in the embodiment of the present disclosure may be combined with each other if there is no contradiction.

It should be noted that like numerals and letters denote like items in the following figures, therefore, once an item is defined in one figure, it does not require further discussion in subsequent figures.

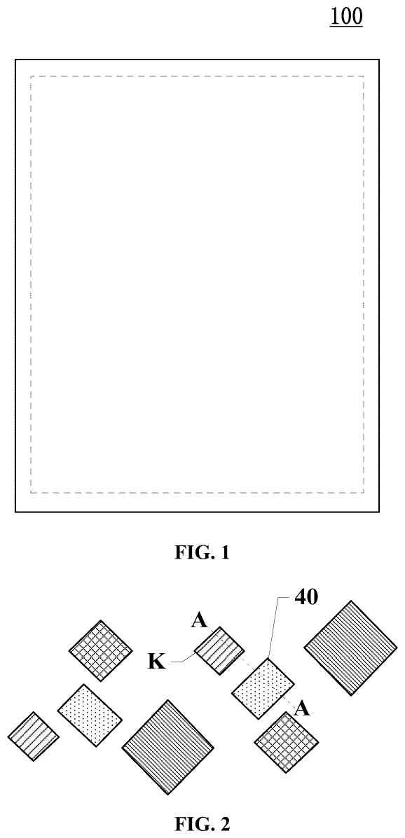

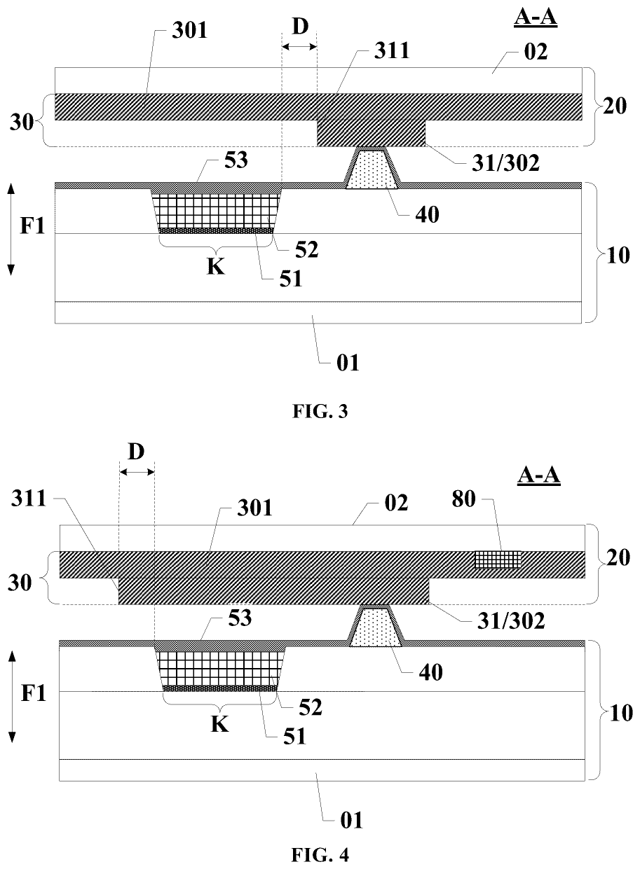

The present disclosure provides a display panel and a display device. FIG. 1 is a top view structure diagram of an exemplary display panel according to various disclosed embodiments of the present disclosure. FIG. 2 is a schematic diagram of an exemplary pixel distribution of the display panel according to various disclosed embodiments of the present disclosure. FIG. 3 is an exemplary AA-sectional view of FIG. 2. FIG. 4 is another exemplary AA-sectional view of FIG. 2. As shown in FIGS. 1-4, a display panel 100 provided by the present disclosure may include a first base substrate 10 and a second base substrate 20 disposed opposite to each other, and a support pillar 40 disposed between the first base substrate 10 and the second base substrate 20.

The first base substrate 10 may include a first substrate 01 and a plurality of pixel openings K disposed on the side of the first substrate 01 facing the second base substrate 20. The second base substrate 20 may include a second substrate 02 and a first insulation layer 30 disposed on the side of the second substrate 02 facing the first base substrate 10. The first insulation layer 30 may include a first insulation portion 31. In a first direction F1, the first insulation portion 31 may overlap with the support pillar 40, and the first direction F1 may be perpendicular to the plane where the first substrate 01 is located.

The first insulation portion 31 may include a first edge 311. The orthographic projection of the first edge 311 on the first substrate 01 may be located outside the orthographic projection of the pixel opening K on the first substrate 01. The orthographic projection of the first edge 311 is on the first substrate 01 and the orthographic projection of the pixel opening K on the first substrate 01 may have a first preset distance D, and D>0.

It should be noted that FIG. 1 only takes a display panel with a rectangular structure as an example, and does not limit the actual shape of the display panel. In some other embodiments of the present disclosure, the shape of the display panel may also be embodied as a rounded rectangle, round or other shaped. FIG. 2 only schematically shows a kind of pixel arrangement of the display panel, and does not limit the actual pixel arrangement structure of the display panel. FIG. 3 only schematically shows a film layer structure of the display panel, and does not represent the number and thickness of the film layers actually included in the display panel.

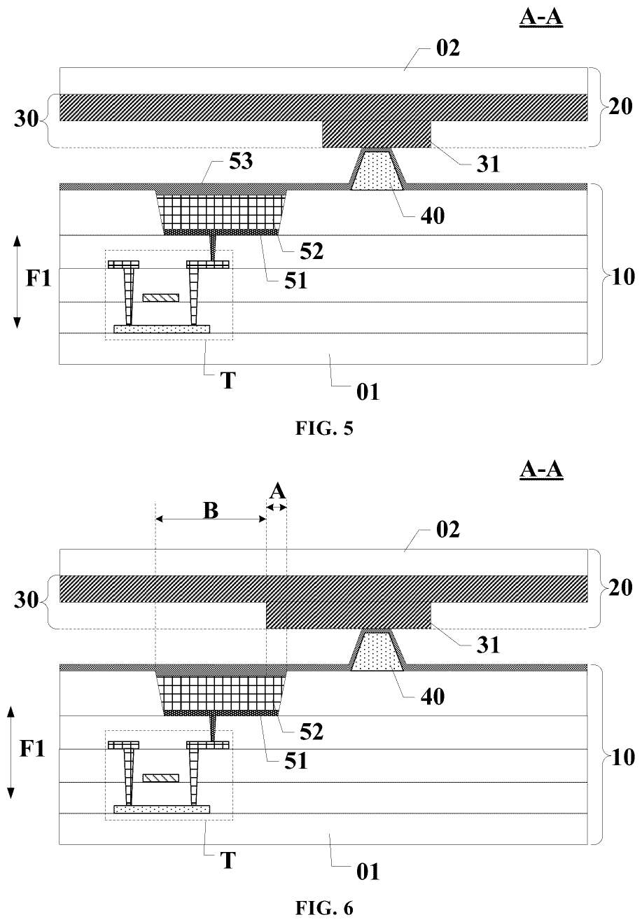

In one embodiment, the display panel may be a display panel using the organic light-emitting diode display technology, that is, an organic light-emitting diode (OLED) display panel. The pixel opening K of the first substrate 10 may be filled with a light-emitting material layer 52. In the first direction F1, the upper and lower sides of the light-emitting material layer 52 may be respectively provided with an anode 51 and a cathode 53, and the anode 51 and the cathode 53 may be both located on the first base substrate 10. The anode 51 may be located at the side of the cathode 53 facing the first substrate 01. When appropriate voltages are provided to the anode 51 and the cathode 53 respectively, holes in the anode 51 and electrons in the cathode 53 may combine in the light-emitting material layer 52 to generate bright light. Compared with the thin-film field-effect transistor liquid crystal displays, OLED display devices may have the characteristics of high visibility and high brightness, and may be more power-saving, lighter in weight, and thinner in thickness. In one embodiment, a driving layer may be provided between the anode 51 and the first substrate 01, and the driving layer may include a plurality of transistors T. For example, referring to FIG. 5, which is another exemplary AA cross-sectional view of FIG. 2. Compared with FIG. 3 and FIG. 4, FIG. 5 refines the driving layer, and the driving layer in FIG. 5 is only an example. The anode 51 may be connected to the transistor T, and the driving voltage may be obtained through the transistor T.

In one embodiment of the present disclosure, a second base substrate 20 disposed opposite to the first base substrate 10 may be introduced into the display panel. The second base substrate 20 may include a second substrate 02 and an insulation layer 30 disposed on the side of the second substrate 02 facing the first base substrate 10. The first insulation layer 30 may include a first insulation portion 31. The present disclosure further defines that the first edge of the first insulation portion 31 may be located outside the orthographic projection of the pixel opening K on the first substrate 01. The first edge 311 may be regarded as the outer contour corresponding to the orthographic projection of the first insulation portion 31 on the first substrate 01. For example, in the first direction F1, the first edge corresponding to the outer contour of the first insulation portion 31 may not overlap with the pixel opening K, and the orthographic projection of the first edge on the first substrate 01 may have a certain interval with the pixel opening K. The width of the interval may be regarded as a first preset distance D between them, and D may be greater than zero.

FIG. 6 is a schematic diagram of a film layer when the first insulation portion 31 is extended above the pixel opening K. It may be seen that, above the same pixel opening K, a first insulation portion 31 may be disposed in a partial region (for example, region A). However, some regions (such as area B) may not be provided with the first insulation portion 31, resulting in the appearance of two kinds of film layers above the same pixel opening K. During the screen display process, the light of the pixel opening K passes through the above two films of a stacked structure, there may be a display difference between the region A and the region B, and there may be a problem that the first edge of the first insulation portion 31 may be visible in the region A, which may affect the overall display effect of the display panel. Further, if the distance between the first edge and the orthographic projection of the pixel opening K on the first substrate 01 is relatively short, in the case of light output at a large viewing angle, the light with a larger exit angle may be blocked by the first edge of the first insulation portion. In this way, two kinds of film layer stacked structures may appear above the same pixel opening, causing the first edge of the first insulation portion 31 to be visible and affecting the display effect.

For this reason, in one embodiment of the present disclosure, the orthographic projection of the first insulation portion 31 on the first substrate 01 may be set outside the orthographic projection of the pixel opening K on the first substrate 01. At this time, the corresponding first insulation portion 31 may have two disposition ways. For the first disposition way, as shown in FIG. 3, the orthographic projection of the first insulation portion 31 on the first substrate 01 may be located at the periphery of the pixel opening K. In the first direction F1, the orthographic projection of the first insulation portion 31 on the first substrate 01 may not overlap with the pixel opening K to prevent the first insulation portion 31 from extending into the pixel opening K. Accordingly, the upper portion of the pixel opening K may include only one film layer structure, thereby avoiding different stacking situations of two layers in the upper area of the pixel opening K. For the second disposition way, as shown in FIG. 4, the orthographic projection of the first insulation portion 31 on the first substrate 01 may cover the orthographic projection of the pixel opening K on the first substrate 01. On this basis, the edge of the first insulation portion 31 may extend to the periphery of the pixel opening K. At this time, there may be only one film stacked structure above the pixel opening K, which may also avoid two different stacked structures in the area above the pixel opening K. In addition, by setting the orthographic projections of the first edge and the pixel opening K on the first substrate 01 to have a first preset distance D, for example, there may be a certain safety range between the two, such that light may be emitted at a large viewing angle. Further, it may be possible to prevent the light with a relatively large exiting angle from being blocked by the first edge of the first insulation portion, for example, to avoid the problem that the first edge of the first insulation portion 31 is visible. That is to say, in the display panel provided by the embodiment of the present disclosure, only one kind of film layer structure may be arranged above the pixel opening K. Such a configuration may reduce or avoid the problem that the edge of the first insulation portion 31 is visible, thus improving the overall display effect of the display panel.

In one embodiment of the present disclosure, a support pillar 40 may be introduced between the first base substrate 10 and the second base substrate 20, and in the first direction F1, the first insulation portion 31 may overlap the support pillar 40 such that the first insulation portion 31 may play a role of a padding, and may be beneficial to realize the effective support of the first base substrate 10 and the second base substrate 20 by the support pillar 40.

Further, referring to FIG. 3 and FIG. 4, in another embodiment of the present disclosure, the preset distance between the orthographic projection of the first edge 311 on the first substrate 01 and the orthographic projection of the pixel opening K on the first substrate 01 may satisfy: D≥4 μm. For example, the value range of the first preset distance D may be 4 μm-7.5 μm, such as 4 μm, 5 μm, 6 μm, 7 μm, or 7.5 μm, etc.

In the process of manufacturing the display panel, after the first base substrate 10 and the second base substrate 20 are manufactured, the first base substrate 10 and the second base substrate 20 may be bonded in position. During the alignment bonding process, according to the current process capability, the bonding accuracy may be controlled at 4 μm, for example, the alignment deviation between the first base substrate 10 and the second base substrate 20 may be less than or equal to 4 μm. In one embodiment of the present disclosure, when the first preset distance between the orthographic projection of the first edge on the first substrate 01 and the orthographic projection of the pixel opening K on the first substrate 01 is set to be greater than or equal to 4 μm, it may be equivalent to being greater than or equal to the positioning accuracy of the first base substrate 10 and the second base substrate 20. Therefore, even if there is an alignment deviation between the first base substrate 10 and the second base substrate 20 during the manufacturing process, and the relative position between the first insulation portion 31 and the pixel opening K may change, the first insulation portion 31 may not extend above the pixel opening K. For example, in the first direction F1, the first insulation portion 31 may not overlap with the pixel opening K. Thus, it may also be beneficial to avoid the occurrence of two different film layer structures above the pixel opening K, which may also be beneficial to improving the overall display effect of the display panel.

Further, referring to FIG. 3 and FIG. 4, in another embodiment of the present disclosure, the first insulation layer 30 may include a first sub-insulation layer 301 and a second sub-insulation layer 302, and in the first direction F1, the first sub-insulation layer 301 may be located between the second sub-insulation layer 302 and the second substrate 02. The orthographic projections of the pixel opening K and the first insulation portion 31 on the first substrate 01 may be located within the scope of the orthographic projection of the first sub-insulation layer 301 on the first substrate 01. The first insulation portion 31 may be located on the second sub-insulation layer 302.

In one embodiment, the first insulation layer 30 may include a first sub-insulation layer 301 and a second sub-insulation layer 302 stacked on the second substrate 02. The second sub-insulation layer 302 may be located on the side of the first sub-insulation layer 301 away from the second substrate 02. The first sub-insulation layer 301 may be regarded as a planar structure covering the second substrate 02, for example, the first sub-insulation layer 301 may be continuously arranged in the entire layer; and the first insulation portion 31 may be located on the second sub-insulation layer 302. When the first insulation layer 30 includes two sub-insulation layers, it may be equivalent to increasing the distance between the second substrate 02 and the first substrate 01. When forming a metal film layer between the second substrate 02 and the first insulation layer 30, it may be beneficial to increase the distance between the metal film layer and the metal film layer on the first substrate, thereby helping to reduce the capacitance between the metal film layer on the first substrate and the metal film layer on the second metal substrate. For example, in the first substrate 10, the film layer where the cathode 53 is located may be the metal film layer closest to the second substrate 20 in the first substrate 10. When a metal film layer such as the touch electrode 80 is introduced on the second substrate 20, for example, referring to FIG. 4, the touch electrode 80 may be disposed between the first insulation layer 30 and the second substrate 02. When the first insulation layer 30 is a double-layer structure, for example, it includes a stacked first sub-insulation layer 301 and the second sub-insulation layer 302, the distance between the touch electrode 80 and the cathode 53 in the first substrate 10 may be increased, which may be beneficial to reduce the capacitance between the touch electrode and the cathode, and reduce the impact of electrical signal of the cathode on the touch signal; and it may be beneficial to improve the touch accuracy.

In one embodiment, referring to FIG. 3, in the first direction F1, the first insulating portion 31 may not overlap the pixel opening K, and the second sub-insulation layer 302 may have a hollow structure corresponding to the pixel opening K. In the first direction F1, the orthographic projection of the pixel opening K on the plane where the second sub-insulation layer 302 is located may be located in the above-mentioned hollow structure, and the orthographic projection of the first insulation portion 31 on the first substrate 01 may be located within the range of the orthographic projection of the first sub-insulation layer 301 on the first substrate 01. At this time, above the pixel opening K, there may be only one kind of film layer stacked structure, that is, including the first sub-insulation layer 301 and the second substrate 02. The first insulation portion 31 may not extend to the top of the pixel opening K. Thus, it may also be beneficial to avoid the problem that the edge of the first insulation portion 31 is visible, and may be beneficial to improve the overall display effect of the display panel.

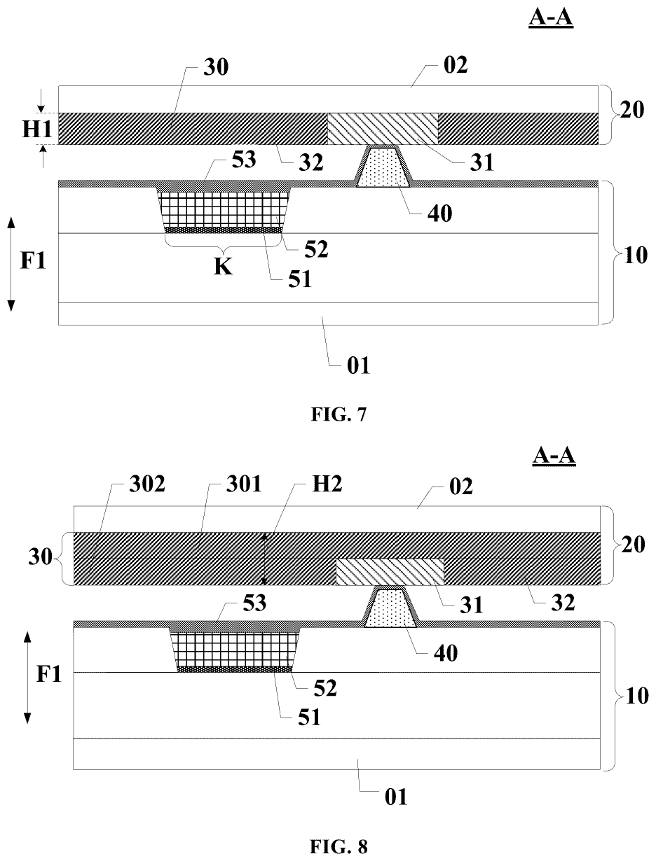

FIG. 7 illustrates another exemplary AA-sectional view of FIG. 2. This embodiment refines another possible film structure of the first insulation layer 30. This embodiment shows a solution for the first insulation layer 30 being a single-layer structure.

As shown in FIG. 7, in one embodiment of the present disclosure, the first insulation layer 30 may further include a second insulation portion 32. The second insulation portion 32 may be located between adjacent first insulation portions 31 and may be connected to the first insulation portion 31 continuously.

Specifically, this embodiment shows that the first insulation layer 30 may be embodied as a single film layer in the display panel. The first insulation layer 30 may include the first insulation portion 31 and the second insulation portion 32 disposed between the first insulation portions 31. For example, the first insulation portion 31 and the second insulation portion 32 may be integrally and continuously disposed to form the first insulation layer 30 with a planar structure. To clearly illustrate and distinguish the first insulation portion 31 and the second insulation portion 32 in the first insulation layer 30, the first insulation portion 31 and the second insulation portion 32 are filled differently in FIG. 7, but the materials of the first insulation portion 31 and the second insulation portion 32 may not be limited. In one embodiment, the first insulation portion 31 and the second insulation portion 32 may be made of a same material in a same process. When the second insulation portion 32 is introduced into the first insulation layer 30, because the second insulation portion 32 is located between the first insulation portion 31 and provided continuously with the first insulation portion 31, there may be no gap between the first insulation portion 31 and the second insulation portion 31. In the first direction F1, the orthographic projection of the pixel opening K on the first substrate 01 may be within the range of the orthographic projection of the second insulation portion 32 on the first substrate 01. At this time, the film layer structure above the pixel opening K may also include only one type, specifically the second insulation portion 32 and the second substrate 02 arranged in stacked layers. The problem that the edge of the first insulation portion 31 is visible due to the difference in layer structure may be avoided and may also be beneficial to improving the overall display effect of the display panel. In addition, this embodiment may be also beneficial to reduce the number of film layers above the pixel opening K, thereby improving the overall transmittance of the display panel.

Further, referring to FIG. 7, in one embodiment of the present disclosure, the thickness of the first insulation layer 30 may be H1, and 0.5 μm≤H1≤1 μm. In the existing film forming process, an insulation layer less than or equal to 1 μm may be formed by one-time film-forming process. When the thickness of the first insulation layer 30 is between 0.5 μm and 1 μm, one-time forming process may be used to form the film structure, that is to say, the first insulation layer 30 in the embodiment of FIG. 7 may be a single-layer structure. When the first insulation layer 30 with a single-layer structure is used, it may be beneficial to reduce the thickness of the film layer above the pixel opening K, thereby reducing the influence of the film layer above the pixel opening K on the transmittance of light, thus helping to ensure the overall transmittance of the displays panel. In addition, when the first insulation layer 30 is formed with a single-layer structure, it may also be beneficial to simplify the production process of the display panel and reduce the production cost.

FIG. 8 is another exemplary AA-sectional view of FIG. 2. This embodiment refines another possible film structure of the first insulation layer 30. This embodiment shows the scheme that the first insulation layer 30 may include two sub-insulation layers.

As shown in FIG. 8, in one embodiment of the present disclosure, the first insulation layer 30 may include a first sub-insulation layer 301 and a second sub-insulation layer 302. In the first direction F1, the first sub-insulation layer 301 may be located between the second sub-insulation layer 302 and the second substrate 02. Both the first insulation portion 31 and the second insulation portion 32 may be located in the second sub-insulation layer 302.

In one embodiment, the first insulation layer 30 may include a first sub-insulation layer 301 and a second sub-insulation layer 302 stacked on the second substrate 02. The second sub-insulation layer 302 may be located on the side of the first sub-insulation layer 301 away from the second substrate 02. The first sub-insulation layer 301 may be regarded as a planar structure covering the second substrate 02. The second sub-insulation layer 302 may include a first insulation portion 31 and a second insulation portion 32. The second insulation portion 32 may be located between adjacent first insulation portions 31, and may be arranged continuously with the first insulation portion 31. To clarify and distinguish the first insulation portion 31 and the second insulation portion 32 in the first insulation layer 30, the first insulation portion 31 and the second insulation portion 32 are filled differently in FIG. 8, but the materials of the first insulation portion 31 and the second insulation portion 32 are not limited. In one embodiment, the first insulation portion 31 and the second insulation portion 32 may be made of the same material in the same process. When the second insulation portion 32 is introduced into the first insulation layer 30, because the second insulation portion 32 may be located between the first insulation portion 31 and provided continuously with the first insulation portion 31, there may be no gap between the first insulation portion 31 and the second insulation portion 31, and the first insulation portion 31 and the second insulation portion 32 may integrally constitute the second sub-insulation layer 302 of a planar structure. The orthographic projection of the pixel opening K on the first substrate 01 may be located within the range of the orthographic projection of the second insulation portion 32 on the first substrate 01. For example, when the first insulation layer 30 includes two sub-insulation layers, and when second sub-insulation layer 302 includes the second insulation portion 32, the area above the pixel opening K may also include only one film stacked structure, that is, the stacked structure may compose of the second insulation portion 32, the first sub-insulation layer 301 and the second substrate 02. Therefore, it may also be beneficial to avoid the problem that the edge of the first insulation portion 31 is visible due to different film layer structures above the same pixel opening K, and it may also be beneficial to improve the overall display effect of the display panel.

In one embodiment, the thickness of the first insulation layer 30 may be H2, and 1 μm<H2≤1.5 μm. When using the existing process to form the insulation layer, the thickest film structure may only be formed within 1 μm in one process. When the thickness of the first insulation layer 30 in the embodiment shown in FIG. 8 is greater than 1 μm and less than 1.5 μm, it may be considered that the first insulation layer 30 is a two-sublayer structure formed by two processes, for example, after the first sub-insulation layer 301 is formed on the second substrate 02, the second sub-insulation layer 302 may be on the side of the first sub-insulation layer 301 away from the second substrate 02. The second sub-insulation layer 302 may only include the first insulation portion 31, or may include both the first insulation portion 31 and the second insulation portion 32. When a metal structure is introduced between the second substrate 02 and the first insulation layer 30, this embodiment may be beneficial to increase the distance between metal structure on the second base substrate 20 and the metal layer on the first base substrate 10 by introducing two sub-insulating layers in the first insulation layer; and the coupling capacitance between them may be reduced.

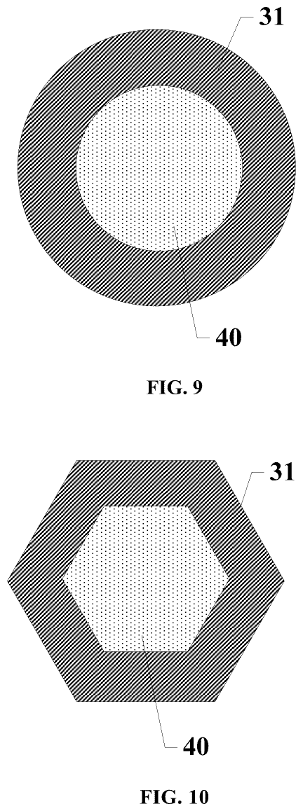

FIG. 9 is a diagram showing an exemplary relative positional relationship between the support pillar 40 and the first insulation portion 31 in the display panel. In this embodiment, the configuration that the orthographic projections of the support pillar 40 and the first insulation portion 31 on the first substrate 01 are both circles is sued as an example.

As shown in FIG. 9, in another embodiment of the present disclosure, the orthographic projection of the first insulation portion 31 on the first substrate 01 and the orthographic projection of the support pillar 40 on the first substrate 01 may be similar figures.

Referring to FIG. 9 and FIG. 2, assuming that the orthographic projection of the first insulation portion 31 on the first substrate 01 is a first projection, and the orthographic projection of the support pillar 40 on the first substrate 01 is a second projection, in one embodiment, the geometric center of the first projection may coincide with the geometric center of the second projection. In such a configuration, when the second base substrate 20 is squeezed by an external force, the force may be transmitted from the first insulation portion 31 to the support pillar 40 as uniformly as possible, which may be beneficial to reduce the relative force between the support pillar 40 and the first insulation portion 31. The extent of the displacement may be beneficial to improve the supporting performance of the support pillar 40 on the first base substrate 10 and the second base substrate 20.

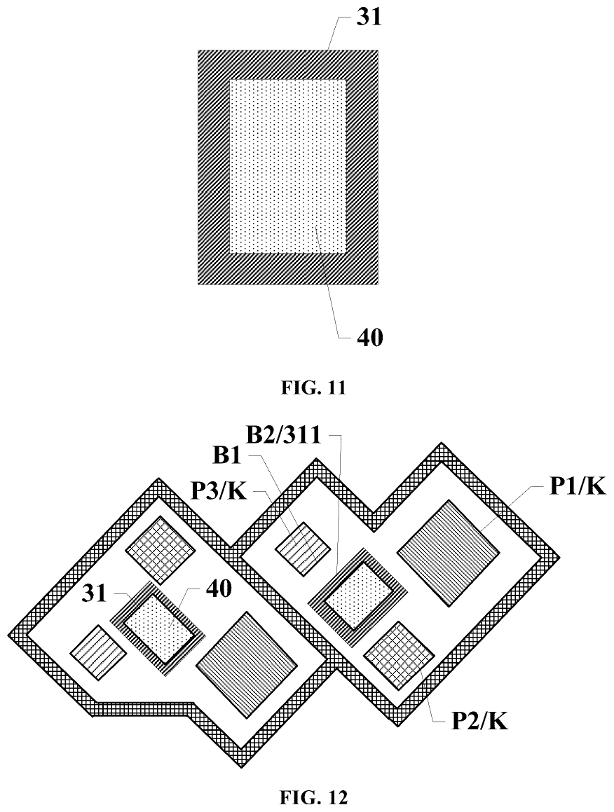

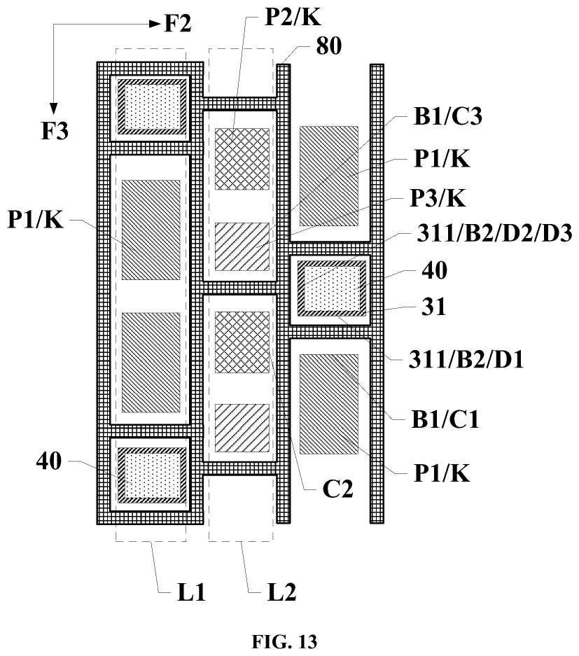

It should be noted that the setting of the first projection and the second projection as circles in FIG. 9 is only for illustration, and does not limit the shapes of the first projection and the second projection. In some other embodiments of the present disclosure, the first projection and the second projection may also be embodied as ellipses or polygons, etc. For example, referring to FIG. 10 and FIG. 11, the first projection and the second projection in the embodiment shown in FIG. 10 are both embodied as a hexagonal structure, and the first projection and the second projection in the embodiment shown in FIG. 11 are all embodied as a rectangle structure. FIG. 10 and FIG. 11 respectively show another relative positional relationship between the support pillar 40 and the first insulation portion 31 in the display panel.

Further, referring to FIG. 3, in another embodiment of the present disclosure, in the first direction F1, the first insulation portion 31 may not overlap the pixel opening K. That is to say, the orthographic projection of the first insulation portion 31 on the first substrate 01 is located at the periphery of the pixel opening K as a whole, and the first insulation portion 31 may not extend to the area above the pixel opening K. At this time, the number of film layers above the pixel opening K is relatively small, which may be beneficial to ensure the overall transmittance of the display panel. The following embodiments will be described first by taking the approach that the first insulation layer 30 does not overlap the pixel opening K in the first direction F1 as an example.

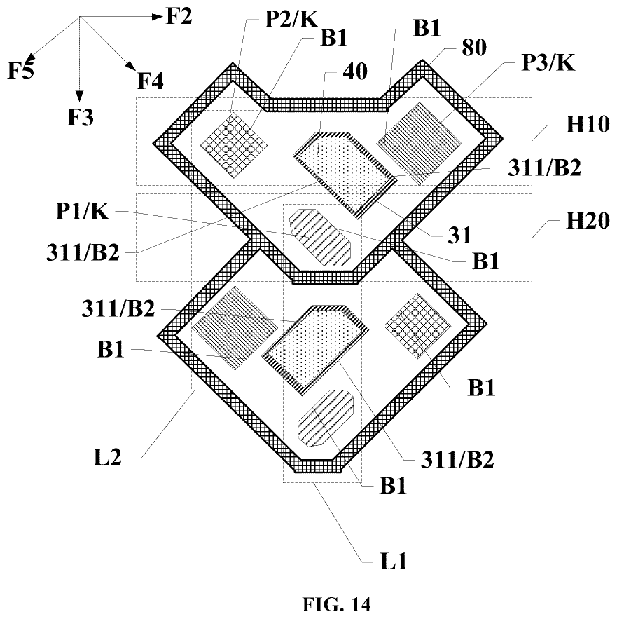

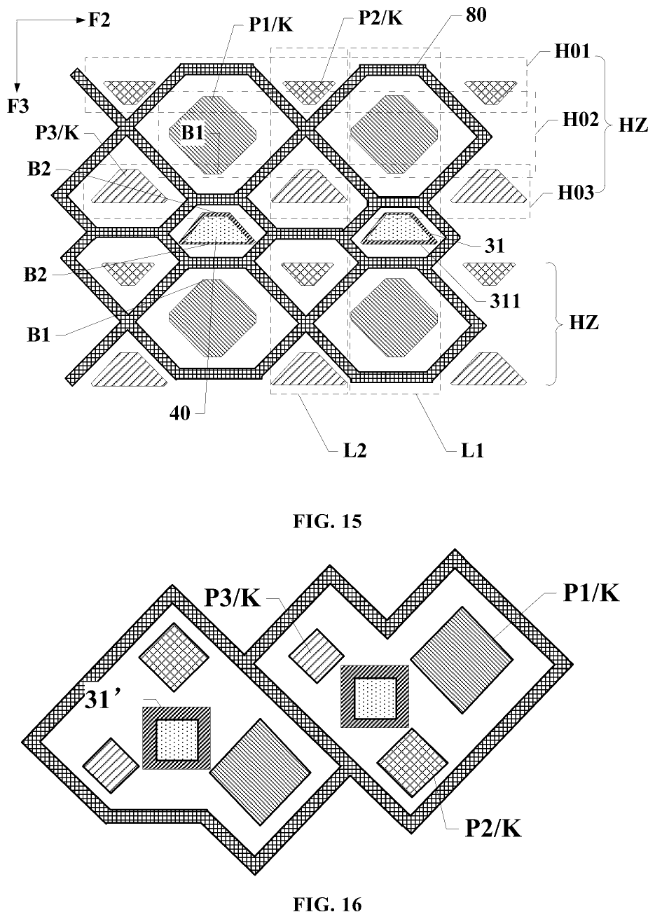

FIG. 12 is a diagram showing a relative positional relationship between the pixel opening K and the adjacent first insulation portion 31 in the display panel. FIG. 13, FIG. 14 and FIG. 15 are schematic diagrams of several arrangements of the pixel opening K, the support pillars 40 and the first insulation portion 31. FIG. 12 and FIG. 13 all take the configurations that the orthographic projections of the pixel opening K, the first insulation portion 31 and the support pillar 40 on the first substrate 01 are square-shaped as examples for illustration, and FIG. 14 and FIG. 15 show other shapes of the first insulation portion 31 and the support pillar 40.

In one embodiment, the display panel may include sub-pixels P1 of a first color, sub-pixels P2 of a second color and sub-pixels P3 of a third color, and the sub-pixels of the three colors may be respectively provided with pixel openings K correspondingly. It should be noted that the sub-pixel mentioned in the embodiment of the present disclosure may include a driving circuit and a light-emitting element electrically connected to the driving circuit. The driving circuit may be located in the driving layer, and the light-emitting element may include, for example, the anode 51, the light-emitting material layer 52 and the cathode 53 in some of the aforementioned embodiments. The light-emitting material layer 52 may be at least partially located within the pixel opening. The light-emitting material layer 52 may be a multilayer structure including an electron injection layer, an electron transport layer, a light-emitting layer, a hole transport layer, and a hole injection layer. Sub-pixels of different colors may correspond to different light-emitting layers, and other layers may be shared.

Referring to FIG. 12 to FIG. 15, in one embodiment of the present disclosure, in the first direction F1, the first insulation portion 31 may not overlap with the pixel opening K; and the shape of the orthographic projection of at least one pixel opening K on the first substrate 01 may be a first polygon. The shape of the orthographic projection of the first insulation portion 31 on the first substrate 01 may be a second polygon. In the pixel opening K and the first insulation portion 31 arranged adjacently, the first polygon may include a first sub-edge B1, the second polygon may include the aforementioned first edge 311. The first edge 311 may include a second sub-edge B2. The first sub-edge B1 and the second sub-edge B2 may be adjacent and parallel. The first sub-edge B1 and the second sub-edge B2 mentioned in this embodiment may be adjacent, which may mean that no pixel opening and the first insulation portion are provided between the first sub-edge B1 and the second sub-edge B2.

Specifically, this embodiment shows a scheme in which one first insulation portion 31 is adjacent to at least three pixel openings K. Taking the first insulation portion 31 and one of the adjacent pixel openings K as an example, the first polygon of the pixel opening K may include a first sub-edge B1 adjacent to the first insulation portion 31, and the first insulation portion 31 may include a second sub-edge B2 adjacent to the pixel opening K, and the first sub-edge B1 and the second sub-edges B2 may be parallel. FIG. 16 shows another exemplary arrangement relationship between the first insulation portion and the pixel opening. When the first insulation portion 31 is disposed in the form shown in FIG. 16, that is to say, when the edge of the first insulation portion 31 is not parallel to the edge of the pixel opening K, the boundary of the first insulation portion 31 may be too close to the pixel opening K, for example, the corner of the first insulation portion 31 may be too close to the pixel opening K. During the alignment bonding process, a portion of the first insulation portion 31 may fall into the space above the pixel opening K due to alignment deviation, resulting in two different film stack structures appearing in the upper area of the same pixel opening, and resulting in the problem that the edges of the first insulation portion 31 are visible. Therefore, when the present disclosure sets the first sub-edge corresponding to the pixel opening K and the second sub-edge corresponding to the first insulation portion 31 to be parallel, it may beneficial to prevent the first insulation portion 31 from extending to the upper portion of the pixel opening K, and at the same time, it may also be possible to rationally utilize the space between the pixel openings K to set up the support pillar 40, while not affecting the aperture ratio of the display panel, it may also be beneficial to increase the area of the support pillars 40 and the arrangement density of the support pillars 40, and improve the supporting performance of the support pillars 40 for the first base substrate 10 and the second base substrate 20. It has been found that, compared to the way in which the edges of the support pillars 40 are not parallel to the edges of the pixel opening K, when the first sub-edge B1 and the second sub-edge B2 are set to be parallel in the present disclosure, the arrangement density of the support pillars 40 in the display area may be increased to more than 10%, which may greatly improve the support performance of the support pillars 40. The arrangement density may refer to the ratio between the total area of the orthographic projections of the support pillars 40 on the first substrate 01 and the total area of the display area of the display panel.

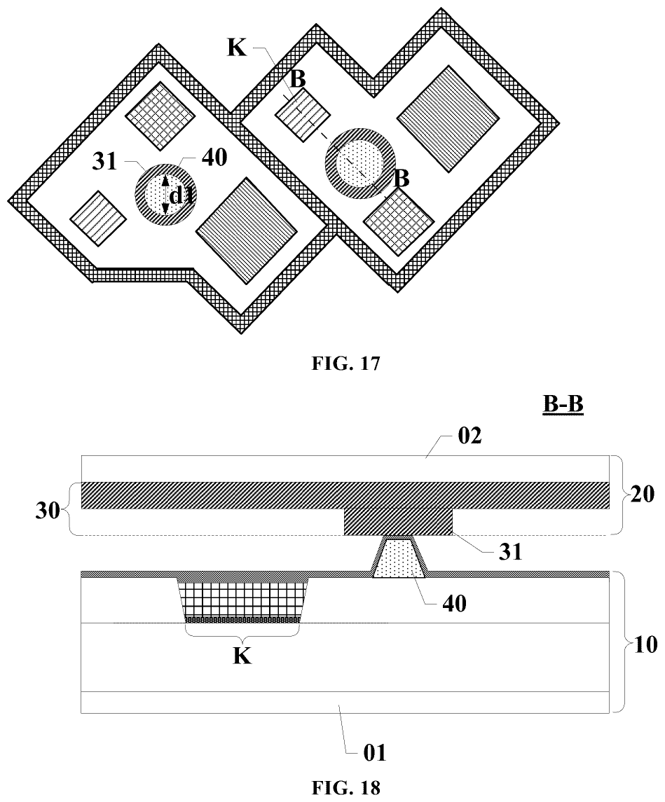

In the embodiment shown in FIG. 12, the orthographic projections of the pixel opening K, the first insulation portion 31 and the support pillar 40 on the first substrate 01 are all square for illustration, but the actual shapes of the three may not be limited. In some other embodiments of the present disclosure, when the support pillar 40 and the first insulation portion 31 have a similar pattern, it may also set that the similar pattern is different from the shape of the pixel opening K, an example is shown in FIG. 17 that is another exemplary diagram of the relative position relationship between the pixel opening K and the adjacent first insulation portion 31 in the display panel. As shown in FIG. 17, the shape of the orthographic projection of the pixel opening K on the first substrate 01 is a square, and the shape of the orthographic projection of the support pillar 40 and the first insulation portion 31 on the first substrate 01 is a circle. When the support pillar 40 and the first insulation part 31 of the circular structure are provided between the pixel openings K of the square structure, compared with the configuration that the first support pillar 40 is with the square structure and the edges of the support pillar 40 does not overlap with the edges of the pixel opening K adjacent to the first support pillar, the present disclosure may increase the area of the orthographic projection of the support pillar 40 on the first substrate 01 in a limited space. The diameter of the orthographic projection of the first pillar 40 on the first substrate 01 may reach more than 24 μm, and the arrangement density of the support pillars 40 may be increased to more than 7.5%, which may also be beneficial to improve the support performance of the support pillars 40 to the first base substrate 10 and the second base substrate 20.

It should be noted that the orthographic projection of the support pillars on the first substrate mentioned in the embodiment of the present disclosure may refer to the orthographic projection of the surface of the support pillars adjacent to the first substrate on the first substrate.

FIG. 18 is a BB-sectional view of FIG. 17. As shown in FIGS. 17-18, in one embodiment of the present disclosure, the orthographic projection of the first insulation portion 31 on the first substrate 01 may be a first circle. The diameter of the first circle may be d1, and d1≥10 μm.

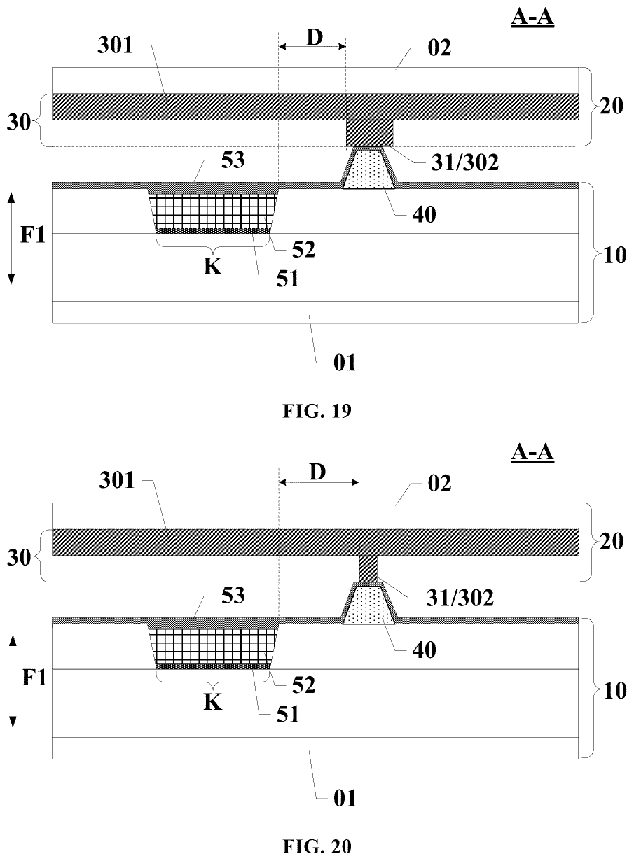

In the first direction F1, when the first insulation portion 31 overlaps with the support pillar 40, the orthographic projection of the first insulation portion 31 on the first substrate 01 may be assumed as a first circle, and the orthographic projection of the support pillar 40 on the first insulation portion 31 may be assumed as a second circle. In one embodiment, the first circle and the second circle may be concentric circles. At this time, there may be three possible settings for the first circle and the second circle. The first one is that the diameter of the first circle may be larger than the diameter of the second circle, as shown in FIG. 17 and FIG. 18. The second one may be that the diameter of the first circle may be equal to the diameter of the second circle, as shown in FIG. 19. The third one may be that the diameter of the first circle may be smaller than the diameter of the second circle, as shown in FIG. 20. FIG. 19 and FIG. 20 are respectively another exemplary AA-sectional view of FIG. 2. When the first circle and the second circle are set as concentric circles, it may be beneficial to improve the support reliability of the support pillar 40 and the first insulation portion 31. In the embodiment of the present disclosure, the diameter d1 of the first circle corresponding to the first insulation portion 31 may be set to be greater than or equal to 10 μm such that the first insulation portion 31 may play a certain support role on the support pillar 40. When the diameter of the second circle corresponding to the support column 40 is greater than 10 μm, the diameter of the above-mentioned first circle may be increased according to the diameter of the second circle corresponding to the support pillar 40, thereby increasing the contact area between the support pillar 40 and the first portion 31, thereby improving the support reliability between the two.

Further, referring to FIGS. 13 to 15, in one embodiment of the present disclosure, the display panel may include a first pixel column L1 and a second pixel column L2 alternately arranged in the second direction F2. The first pixel column L1 may include a plurality of sub-pixel P1 of a first color arranged in the third direction F3. The second pixel column L2 may include a plurality sub-pixels P2 of a second color and sub-pixels P3 of a third color alternately arranged in the third direction F3. The sub-pixel P1 of the first color, the sub-pixel P2 of the second color and the sub-pixel P3 of the third color may all be correspondingly provided with a pixel opening K.

The orthographic projections of the support pillars 40 and the first insulation portion 31 on the first substrate 01 may be located between the pixel openings K corresponding to at least two partially adjacent sub-pixels P1 of the first color in the first pixel column L1. The adjacent pixel openings K and the first insulation portion 31 may be located in the first pixel column L1.

In one embodiment, the second direction F2 may be the row direction, and the third direction F3 may be the column direction. The first pixel column L1 may include only the sub-pixels P1 of the first color and the sub-pixels P1 of the first color may be arranged in the third direction F3. The second pixel column L2 may include the sub-pixels P2 of the second color and the sub-pixels P3 of the third color arranged alternately in the third direction F3 3. The pixel opening K corresponding to the sub-pixel P1 of the first color may be filled with the light-emitting layer of the first color, the pixel opening K corresponding to sub-pixels P2 of the second color may be filled with the light-emitting layer of the second color, and the pixel opening K corresponding to the sub-pixels P3 of the third color may be filled with the light-emitting layer of the third color.

When the pixel arrangement structure shown in FIG. 13 to FIG. 15 is adopted, there may be a large space between some adjacent sub-pixels P1 of the first color, when the orthographic projection of the support pillar 40 on the first substrate 01 is arranged in the above interval space, the space of the display panel may be rationally utilized, and the introduction of the support pillar 40 may not affect the aperture ratio of the display panel. In one embodiment, the support pillars 40 may be provided in the above-mentioned space corresponding to each first pixel support pillar L1, which may be beneficial to ensure the arrangement density of the support pillars 40, and thereby improving the overall supporting performance of the display panel.

Further, referring to FIG. 13, in one embodiment, in the second direction F2, the pixel opening K corresponding to the sub-pixels P1 of the first color may overlap with the pixel opening K corresponding to the sub-pixels P2 of the second color and the sub-pixels P3 of the third color. Thus, a sub-pixel P1 of the first color and a sub-pixel P2 of the second color and a sub-pixel P3 of the third color overlapped and located at the same side of the sub-pixel P1 of the third color in the second direction F2 may form a pixel unit performing a display function. Such a kind of pixel arrangement structure may be relatively regular, and the manufacturing process may be relatively simple, which may be beneficial to improving the manufacturing efficiency of the display panel.

Further, referring to FIG. 13, the orthographic projection of the pixel opening K corresponding to the sub-pixel P1 of the first color on the first substrate 01 may be a first polygon, and in the first polygon, the first sub-edge B1 may include a sub-edge C1. In the second polygons corresponding to the first insulation portion 31, the second sub-edge B2 may include a sub-edge D1, wherein the sub-edge C1 and the sub-edge D1 may be adjacent and may both extend in the second direction F2;

The orthographic projection of the pixel opening K corresponding to the sub-pixel P2 of the second color on the first substrate may be a first polygon. In the first polygon, the first sub-edge B1 may include the sub-edge C2. In the second polygon corresponding to the first insulation portion 31, the second sub-edge B2 may include a sub-edge D2. The sub-edge C2 and the sub-edge D2 may be adjacent and may both extend in the third direction F3.

The orthographic projection of the pixel opening K corresponding to sub-pixels P3 of the third color on the first substrate 01 may be a first polygon. In the first polygon, the first sub-edge B1 may include the sub-edge C3. In the second polygon corresponding to the first insulation portion 31, the second sub-edge B2 may include a sub-edge D3. The sub-edge C3 and the sub-edge D3 may be adjacent and both extend in the third direction F3.

When the pixel opening K, the support pillars 40 and the first insulation portion 31 adopt the arrangement shown in FIG. 13, the first insulation portion 31 and the support pillar 40 may be located between the pixel openings K corresponding to a portion of the sub-pixels P1 in the first pixel column L1. When the first insulation portion 31 and the edges of the pixel openings K corresponding to sub-pixels adjacent to the first insulation portion 31 are set to be parallel, it may be beneficial to avoid the phenomenon that the first insulation portion falls into the upper portion of the pixel opening K during the alignment and bonding on the display panel because the edges of the first insulation portion 31 may be too close to the pixel openings, and it may be beneficial to avoid different film layer structures in different regions above the pixel opening K, thus helping to avoid the problem that the edge of the first insulating part is visible. Accordingly, it may be beneficial to improve the overall display panel display effect.

In one embodiment, the sub-pixel P1 of the first color may be a blue sub-pixel, and the sub-pixel P2 of the second color and the sub-pixel P3 of the third color may be a red sub-pixel and a green sub-pixel. The light-emitting efficiency of the light-emitting material corresponding to the blue sub-pixel may be relatively low, and the pixel opening K corresponding to the blue sub-pixel may be set larger to compensate for the difference in the light-emitting efficiency between the blue sub-pixel and the red sub-pixel and green sub-pixel.

Further, referring to FIG. 13, FIG. 11 and FIG. 12, in another embodiment of the present disclosure, the first polygon corresponding to the orthographic projection of the first insulation portion 31 on the first substrate and the second polygon corresponding to the orthographic projection of the support pillar 40 on the first substrate 01 may all be rectangles. In one embodiment, the orthographic projection of the pixel opening K on the first substrate 01 may correspond to a rectangle (the first polygon), and the orthographic projection of the support pillar 40 on the first substrate 01 is also a rectangle. The orthographic projection (the second polygon) of the first insulation portion 31 corresponding to the support pillar 40 on the first substrate 01 may also be a rectangle, which may be beneficial to simplify the manufacturing difficulty of the display panel as a whole. In this embodiment, in the first direction F1, the first insulation portion 31 does not overlap the pixel opening K. At this time, in the adjacent first insulation portion 31 and the pixel opening K, the adjacent edges may be set in a parallel. Such a configuration may facilitate to prevent the first insulation portion 31 from extending to a portion of the region above the pixel opening K, and avoid a different film layer structure in the region above the pixel opening K, thereby helping to avoid the problem that the edge of the first insulation portion 31 is visible.

Further, referring to FIG. 14, in one embodiment, the display panel may further include first pixel rows H10 and second pixel rows H20 alternately arranged in the third direction F3. The first pixel row H10 may include the sub-pixels P2 of the second color and the sub-pixels P3 of the third color alternately arranged in the direction F2. The second pixel row H20 may include the sub-pixel P1 of the first color. The orthographic projection of the first insulation portion 31 on the first substrate 01 may be located outside the pixel openings K corresponding to adjacent the sub-pixels P2 of the second color and the sub-pixel P3 of the third color in the second direction F2. The sub-pixels P2 of the second color and the sub-pixel P1 of the first color may be arranged alternately in the fourth direction F4. The sub-pixel P3 of the third color and the sub-pixels P1 of the first color may be alternately arranged in the fifth direction F5. The fourth direction F4 may intersect the fifth direction F5, and the fourth direction F4 and the fifth direction F5 may both intersect the second direction F2 and the third direction F3. In the orthographic projections of the pixel openings K corresponding to the sub-pixel P1 of the first color, the sub-pixels P2 of the second color and the sub-pixels P3 of the third color, all may include first sub-edges B1, the orthographic projections of which and the first substrate 01 may be adjacent. The first sub-edge B1 and the second sub-edge B2 may both extend in the fourth direction F4, or, the first sub-edge B1 and the second sub-edge B2 may both extend in the fifth direction F5. It should be noted that, in the embodiment of the present disclosure, the configuration that the sub-pixel is adjacent to the first insulation portion may mean that, in the arrangement direction of the sub-pixel and the first insulation portion, no other sub-pixel is arranged between them, and the two adjacent edges of the sub-pixel and the first insulation portion may be regarded as the two closest edges of the sub-pixel and the first insulation portion. When the two closest edges of the first insulation portion 31 and the pixel opening corresponding to its adjacent sub-pixel are set to be parallel, it may be beneficial to ensure that the first insulation portion may maintain a certain distance from the pixel opening, while avoiding the first insulation portion falling into the upper region of the pixel opening, it may be beneficial to avoid the problem that the edge of the first insulation portion is visible due to different film layer structures in the upper region of the pixel opening, and thus also be beneficial to improving the overall display effect of the display panel.

In one embodiment, the second direction F2 may be the row direction, the third direction F3 may be the column direction, the fourth direction F4 and the fifth direction F5 may be perpendicular to each other, and the fourth direction F4 and the fifth direction F5 may respectively intersects with the second direction F2 and the third direction F3. The first pixel row H10 may include alternately arranged sub-pixels P2 of the second color and sub-pixels P3 of the third color. The second pixel row H20 may include sub-pixels P1 of the first color arranged in the second direction F2. The embodiment in FIG. 14 shows two pixel units, and each pixel unit may include sub-pixels of three colors. The sub-pixels of three colors in the same pixel unit may form a triangular structure, and the three sub-pixels may be located at the vertices of the triangular structure. At this time, the middle area of the triangular structure may have a larger accommodating space. In this embodiment, the orthographic projection of the support pillar 40 on the first substrate 01 may be located in the triangular structure, and the pixel openings K corresponding to the three sub-pixels may not overlap. That is, the support pillars 40 may be arranged in the accommodating space such that the space of the display panel may be reasonably utilized without affecting the aperture ratio of the display panel.

In one embodiment, the sub-pixel P1 of the first color may be a green sub-pixel, and the sub-pixel P2 of the second color and the sub-pixel P3 of the third color may be red sub-pixels and blue sub-pixels respectively. Considering that the light-emitting efficiency of the light-emitting material corresponding to the blue sub-pixel may be relatively low, the size of the pixel opening K corresponding to the blue sub-pixel may be appropriately increased to compensate for the problem of different light brightness caused by the difference in light-emitting efficiency.

FIG. 15 is a schematic diagram of another exemplary arrangement of the pixel opening K and the support pillars 40 in the display panel provided by one embodiment of the present disclosure. As shown in FIG. 15, in one embodiment, the first edge 311 of the first insulation portion 31 may extend in the second direction F2. The display panel may include a plurality of pixel row group HZ arranged in the third direction F3. The pixel row group HZ may include a first pixel row H01, a second pixel row H02 and a third pixel row H03 arranged in the third direction F3. The first pixel row H01 may include a plurality of sub-pixel P2 of the second color arranged in the second direction F2. The second pixel row H02 may include a plurality of sub-pixels P1 of the first color arranged in the second direction F2. The third pixel row H03 may include a plurality of sub-pixels P3 of the third color arranged in the second direction F2. A first insulation portion 31 may be located between two adjacent pixel row groups HZ. In the third direction F3, the first insulation portion 31 may be located between the pixel openings K corresponding to two adjacent sub-pixels P1 of the first color. The orthographic projection of the pixel opening K corresponding to the sub-pixel P1 of the first color on the first substrate may be a first polygon, and the first sub-edge B1 of the first polygon and the second sub-edge B2 of the first insulation portion 31 may both extend in the second direction F2.

In one embodiment, the second direction F2 may be the row direction, and the third direction F3 may be the column direction. In the pixel arrangement structure of this embodiment, the plurality of pixel row groups HZ may be provided and arranged in the third direction F3, and the pixel row groups HZ may include three types of pixel rows arranged along the third direction F3, which may be respectively the first pixel row H01, the second pixel row H02 and the third pixel row H03. Each pixel row may include sub-pixels of one color, and the colors of the sub-pixels included in the three pixel rows may be different. In the second direction F2, the sub-pixels in the first pixel row H01 and the second pixel row H02 may be alternately arranged, and the sub-pixels in the second pixel row H02 and the third pixel row H03 may be alternately arranged. In such a configuration, in the third direction F3, there may be a large space between two adjacent pixel row groups HZ to set up the support pillar 40. Specifically, there may be a relatively large space between two adjacent sub-pixels of the first color of two adjacent pixel row groups HZ for setting the support pillars 40, thereby rationally utilizing the space of the display panel, ensuring the arrangement density of the support pillars 40 and avoiding the influence of the introduction of the support pillars 40 on the aperture ratio of the display panel.

In the pixel arrangement structure described in this embodiment, the first insulation portion 31 and the support pillar 40 may be disposed between the pixel openings K corresponding to two adjacent sub-pixels P1 of the first color in the third direction F3, and the two sides of the first insulation portion 31 adjacent to the pixel opening K corresponding to the sub-pixel P1 of the first color may be set to be parallel, and both may extend in the second direction F2. Thus, the first insulation portion 31 and the pixel openings K corresponding to the sub-pixel P1 of the first color may have a certain distance to prevent the first insulation portion 31 from falling into the upper region of the pixel openings K to have two different film layer structures above the pixel opening K. Thus, it may help to prevent the edges of the first insulation portion from being visible, and it may also be beneficial to improve the overall display effect of the display panel.

In one embodiment, the sub-pixel P1 of the first color may be a blue sub-pixel, the sub-pixel P2 of the second color may be a red sub-pixel, and the sub-pixel P3 of the third color may be a green sub-pixel. Considering that the light-emitting efficiency of the light-emitting material corresponding to the blue sub-pixel may be relatively low, and the size of the pixel opening K corresponding to the blue sub-pixel may be appropriately increased to compensate for the problem of different light-emitting brightness caused by the difference in light-emitting efficiency.

In one embodiment of the present disclosure, the contour shape of the orthographic projection of the first insulation portion 31 on the first substrate 01 and the contour shape of the orthographic projection of the pixel opening K corresponding to the sub-pixel P2 of or the sub-pixel P3 of the third color on the substrate may be same, the pixel opening K corresponding to the first insulation portion 31 and the sub-pixel P2 of second color may include edges parallel to each other and extending in the second direction, and the first insulation portion 31 and the pixel opening K corresponding to the sub-pixel P3 of third color may include edges parallel to each other and extending in the second direction.

Further, referring to FIG. 15, to ensure the aperture ratio of the display panel, the shape of the pixel openings K of the sub-pixel P2 of the second color and the sub-pixel of the third color in this embodiment may be similar, and in the same pixel row group HZ, the upper bottom of the trapezoid may be set close to the second pixel row H02. The shape of the pixel opening K of the sub-pixel P1 of the first color may be a quasi-square structure formed by cutting the four corners of the square structure. It may be beneficial to rationally utilize the space between two pixel row groups HZ by setting the first insulation portion 31 with a shape similar with the shape of the pixel openings K of the sub-pixels P2 of the second color and the sub-pixels of the third color, and increase the arrangement density of the support pillars 40 as much as possible without affecting the aperture ratio of the display panel.

In this embodiment, the first insulation portion 31 may be adjacent to the sub-pixel P1 of the first color, the sub-pixel P2 of the second color and the sub-pixel P3 of the third color. In the first insulation portion 31 and the adjacent sub-pixel P1 of the first color, the two adjacent sides may be parallel. The first insulation portion 31 and the sub-pixel of the second color P2 adjacent to it may have two sides parallel to each other. The first insulation portion 31 and its adjacent sub-pixel P3 of the third color may also have two sides parallel to each other. Such a configuration may effectively avoid the first insulating portion 31 from extending to the area above the adjacent pixel opening K, thereby avoiding the problem of the first insulation portion 31 having visible edges.

The above embodiments focus on the solution that the first insulation portion may not overlap the pixel opening in the first direction, the solution that the first insulation portion overlaps the pixel opening in the first direction F1 will be described below. Referring to FIG. 4, in one embodiment, the first insulation portion 31 may cover the pixel opening K in the first direction F1. When the first insulation portion 31 overlaps the pixel opening K in the first direction F1, the specific setting method may be that the orthographic projection of the pixel opening K on the first substrate 01 may cover the orthographic projection of the first insulation portion on the first substrate 01, and the edge of the first insulation portion 31 may be located at the periphery of the pixel opening K. In such a configuration, there may be only one film layer structure above the pixel opening K, and the film layer structure may include the above-mentioned first insulation portion 31. When the light-emitting material in the pixel opening K emits light, since the edge of the first insulation portion 31 is located on the periphery of the pixel opening K, the light may not directly irradiate the edge of the first insulation portion 31, which may also be beneficial to reduce or avoid the problem that the edge of the first insulation portion 31 is visible.

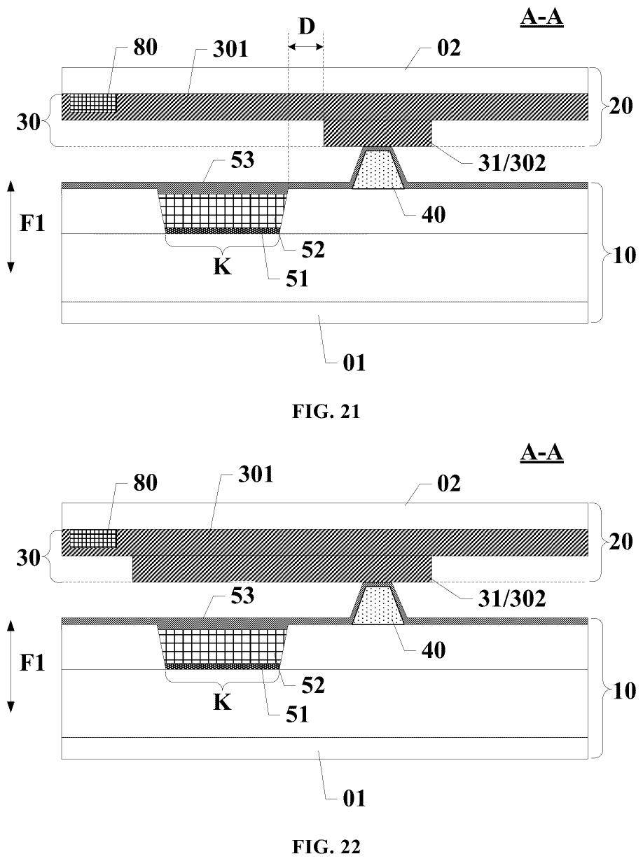

FIG. 21 and FIG. 22 respectively show an AA-sectional view of the display panel in FIG. 2 when the touch layer is provided. This embodiment schematically shows the position of the touch layer in the display panel.

As shown in FIG. 21 and FIG. 22, in one embodiment, the second base substrate 20 may further include a touch layer, and the touch layer may be located between the second substrate 02 and the first insulation layer 30. The touch layer may include a touch electrode 80. In the first direction F1, the touch electrode 80 may not overlap with the pixel opening K, and the touch electrode 80 may not overlap with the first insulation portion 31.

Specifically, this embodiment shows a solution of introducing a touch layer on the second base substrate 20 such that the display panel may have a touch function. The touch layer may include the touch electrodes 80, and the touch electrodes 80 may be arranged in a grid structure as shown in FIGS. 13-15. In the first direction F1, the touch electrode 80 may not overlap with the pixel opening K, which may avoid the problem that the touch electrode 80 is visible during the display process. In the first direction F1, the touch electrode 80 may be arranged not to overlap with the first insulation portion 31, thereby helping to reduce the number of film layers between the touch electrode 80 and the cathode 53 on the first base substrate 10, thus helping to reduce the dielectric constant of the area between them. Accordingly, the capacitance between the touch electrode 80 and the cathode 53 may be reduced, thereby reducing the influence of the capacitance on the touch accuracy, which may be beneficial to improving the overall touch performance of the display panel.

In one embodiment, when the display panel includes the touch electrodes 80, the first insulation layer 30 may include a first sub-insulation layer 301 and a second sub-insulation layer 302, and the first insulation portion 31 may be located in the second sub-insulation layer 302. The introduction of the first insulation portion 31 may increase the distance between the touch electrode 80 and the anode 51, thereby further reducing the capacitance between the touch electrode 80 and the anode 51, which may be beneficial to further improve the overall touch performance of the display panel.

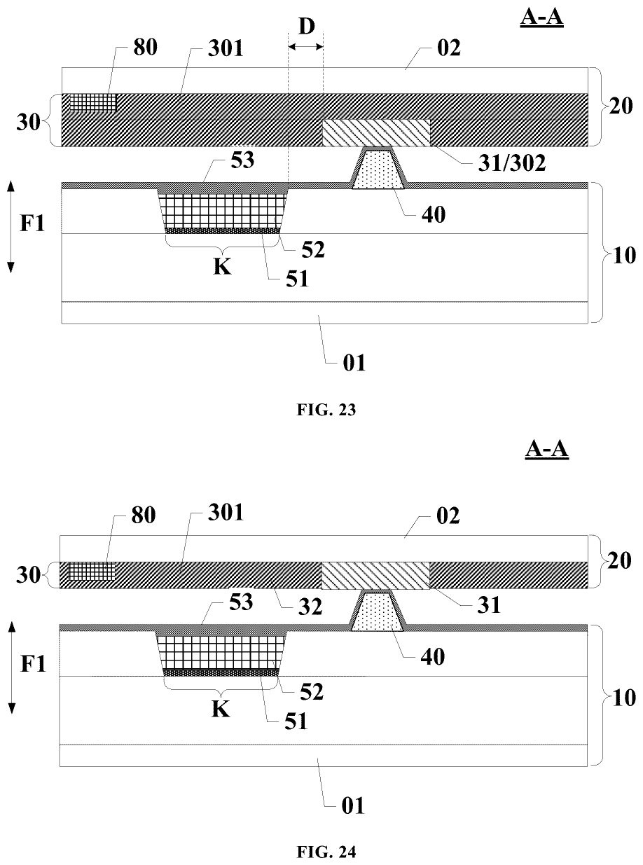

FIG. 23 is another AA-sectional view when the display panel in FIG. 2 is provided with a touch layer. This embodiment shows a solution in which a second insulation portion 32 may be further provided between the first insulation portions 31.

As shown in FIG. 23, in one embodiment, the first insulation layer 30 may further include a second insulation portion 32, and the second insulation portion 32 may be located between adjacent first insulation portions 31 and may be connected to the first insulation portion 31. The first insulation portion 31 may be provided continuously. In the first direction F1, the second insulation portion 32 may cover the touch electrode 80 and the pixel opening K.

In one embodiment, the first insulation layer 30 may include a first sub-insulation layer 301 and a second sub-insulation layer 302. The first insulation portion 31 and the second insulation portion 32 may be located in the second sub-insulation layer 302, and the second insulation portion 32 may cover the pixel opening K. By introducing two sub-insulation layers into the first insulation layer 30, it may be beneficial to increase the distance between the touch electrode 80 and the cathode 53 on the first substrate 10, thereby reducing the capacitance between the touch electrode 80 and the cathode 53, and reducing the effect of the capacitance on the touch accuracy. Thus, the overall touch accuracy of the display panel may be improved.

FIG. 24 is another exemplary AA-sectional view of the display panel in FIG. 2 when a touch layer is provided. When the first insulation layer 30 includes a second insulation portion 32, the first insulation layer 30 may also be embodied as a single layer structure, which may be beneficial to simplify the film layer structure of the display panel and save the production cost.

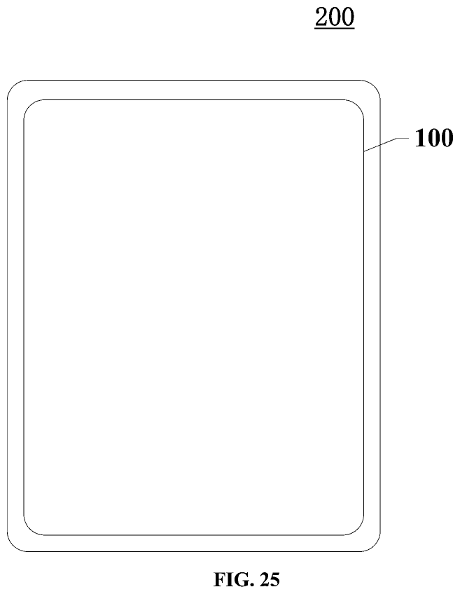

The present disclosure also provides a display device. FIG. 25 is a schematic structural view of an exemplary display device according to various disclosed embodiments of the present disclosure. As shown in FIG. 25, the display device may include the display panel 100 provided by the above implementation of the present disclosure or other appropriate display panel.

It may be understood that the display device 200 provided in the embodiment of the present disclosure may be a mobile phone, a tablet, a computer, a TV, a vehicle display device and other display devices with display functions and touch capabilities, and the present disclosure does not specifically limit this. The display device provided by the embodiments of the present disclosure may have the beneficial effect of the display panel provided by the embodiments of the present disclosure. For details, reference may be made to the specific descriptions of the display panel in the above embodiments, and details will not be repeated herein.

It can be known from the above embodiments that the display panel and the display device provided by the present disclosure may at least achieve the following beneficial effects.

In the display panel and the display device provided by the present disclosure, the second base substrate may include a second substrate and a first insulation layer disposed on a side of the second substrate facing the first base substrate, and the first insulation layer may include a first insulation portion. The disclosure further defines that the first edge of the first insulation portion may be located outside the orthographic projection of the pixel opening on the first substrate. The first edge may be regarded as the outer contour corresponding to the orthographic projection of the first insulation portion on the first substrate. That is to say, in the first direction, the first edge corresponding to the outer contour of the first insulation portion may not overlap with the pixel opening, and there may be a certain interval between the first edge and the orthographic projection of the pixel opening one the first substrate. The width of the interval may be regarded as a first preset distance D between the two, and D may be greater than 0. In such a configuration, only one film layer stacked structure may be included above the pixel opening, thereby avoiding two different stacked structures in the area above the pixel opening. During the image display process, the problem that the edge of the first insulation portion is visible may be effectively reduced or avoided, thus helping to improve the overall display effect of the display panel.

Although some specific embodiments of the present disclosure have been described in detail through examples, those skilled in the art should understand that the above examples are for illustration only and not intended to limit the scope of the present disclosure. Those skilled in the art will appreciate that modifications may be made to the above embodiments without departing from the scope and spirit of the disclosure. The scope of the disclosed may be defined by the appended claims.

What is claimed is:

1. A display panel, comprising:
a first base substrate and a second base substrate oppositely arranged; and
a support pillar disposed between the first base substrate and the second base substrate,
wherein:
the first base substrate includes a first substrate and a plurality of pixel openings disposed on a side of the first substrate facing the second base substrate;
the second base substrate includes a second substrate and a first insulation layer disposed on a side of the second substrate facing the first base substrate;
the first insulation layer includes a first insulation portion;
in a first direction, the first insulation portion overlaps with the support pillar;
the first direction is perpendicular to a plane where the first substrate is located;
the first insulation portion includes a first edge;
an orthographic projection of the first edge on the first substrate is located outside an orthographic projection of the pixel opening on the first substrate;
the orthographic projection of the first edge on the first substrate and the orthographic projection of the pixel opening on the first substrate have a first preset distance D; and
D>0.

2. The display panel according to claim 1, wherein:
D≥4 μm.

3. The display panel according to claim 1, wherein the first insulation layer comprises:
a first sub-insulation layer; and
a second sub-insulation layer,
wherein:
in the first direction, the first sub-insulation layer is located between the second sub-insulation layer and the second substrate;
orthographic projections of the pixel opening and the first insulation portion on the first substrate are located within a range of an orthographic projection of the first sub-insulation layer on the first substrate; and
the first insulation portion is located in the second sub-insulation layer.

4. The display panel according to claim 1, wherein the first insulation layer further comprises:
a second insulation portion located between adjacent first insulation portions and continuously disposed with the first insulation portions.

5. The display panel according to claim 4, wherein:
a thickness of the first insulation layer is H1; and
0.5 μm≤H1≤1 μm

6. The display panel according to claim 4, wherein the first insulation layer comprises:
a first sub-insulation layer; and
a second sub-insulation layer,
wherein:
in the first direction, the first sub-insulation layer is located between the second sub-insulation layer and the second substrate; and
the first insulation portion and the second insulation portion are both located in the second sub-insulation layer.

7. The display panel according to claim 1, wherein:
a thickness of the first insulation layer is H2; and
1 μm<H2≤1.5 μm.

8. The display panel according to claim 1, wherein:
in the first direction, the first insulation portion does not overlap with the pixel opening.

9. The display panel according to claim 8, wherein:
the orthographic projection of the first insulation portion on the first substrate and the orthographic projection of the support pillar on the first substrate have similar patterns.

10. The display panel according to claim 8, wherein:
a shape of an orthographic projection of at least one pixel opening on the first substrate is a first polygon;
a shape of the orthographic projection of the first insulation portion on the first substrate is a second polygon; and
in the pixel opening and the first insulation portion adjacently arranged, the first polygon includes a first sub-edge, the second polygon includes the first edge, and the first edge includes a second sub-edge, and the first sub-edge and the second sub-edge are adjacent and parallel to each other.

11. The display panel according to claim 10, comprising:
a first pixel column and a second pixel column alternately arranged in a second direction,
wherein:
the first pixel column includes a plurality of sub-pixels of a first color arranged in a third direction;
the second pixel column includes a plurality of sub-pixels of a second color and sub-pixels of a third color arranged alternately in the third direction;
the sub-pixels of the first color, the sub-pixels of the second color and the sub-pixels of the third color are all correspondingly provided with the pixel openings;
orthographic projections of the support pillar and the first insulation portion on the first substrate are located between two adjacent pixel openings corresponding to at least a portion of sub-pixels of the first color in the first pixel column; and
the two adjacent pixel openings and the first insulation portion are located in the first pixel column.

12. The display panel according to claim 11, wherein:
in the second direction, the pixel opening corresponding to the sub-pixel of the first color overlaps with both the pixel opening corresponding to the sub-pixel of the second color and the sub-pixel of the third color;
an orthographic projection of the pixel opening corresponding to the sub-pixel of the first color on the first substrate is the first polygon, in the first polygon, the first sub-edge includes a sub-edge C1, in the second polygon, the second sub-edge includes a sub-edge D1, and the sub-edge C1 and the sub-edge D1 are adjacent to each other and both extend in the second direction;
an orthographic projection of the pixel opening corresponding to the sub-pixel of the second color on the first substrate is the first polygon, in the first polygon, the first sub-edge includes a sub-edge C2, in the second polygon, the second sub-edge includes a sub-edge D2, and the sub-edge C2 and the sub-edge D2 are adjacent to each other and both extend in the third direction; and
an orthographic projection of the pixel opening corresponding to the sub-pixel of third color on the first substrate is the first polygon, in the first polygon, the first sub-edge includes a sub-edge C3, in the second polygon, the second sub-edge includes a sub-edge D3 and the sub-edge C3 and the sub-edge D3 are adjacent to other each other and both extend in the third direction.

13. The display panel according to claim 12, wherein:
the first polygon and the second polygon are both rectangles.

14. The display panel according to claim 11, further comprising:
first pixel rows and second pixel rows alternately arranged in the third direction,
wherein
a first pixel row includes the sub-pixels of the second color and the sub-pixels of the third color alternately arranged in the second direction;
a second pixel row includes the sub-pixels of the first color;
the orthographic projection of the first insulation portion on the first substrate is located between pixel openings corresponding to the sub-pixels of the second color and the sub-pixels of the third color adjacently arranged in the second direction;
the sub-pixels of the second color and the sub-pixels of the first color are alternately arranged in a fourth direction;
the sub-pixels of the third color and the sub-pixels of the first color are alternately arranged in a fifth direction;
the fourth direction intersects the fifth direction;
both the fourth direction and the fifth direction intersect the second direction and the third direction;
orthographic projections of the pixel openings corresponding to the sub-pixels of the first color, the sub-pixels of the second color and the sub-pixels of the third color on the first substrate all include first sub-edges adjacent to the orthographic projection of the first insulation portion on the first substrate; and
the first sub-edge and the second sub-edge all extend in the fourth direction, or the first sub-edge and the second sub-edge all extend in the fifth direction.

15. The display panel according to claim 11, wherein:
the first edge extends in the second direction;
the display panel includes a plurality of pixel row groups arranged in the third direction;
a pixel row group includes a first pixel row, a second pixel row and a third pixel row arranged in the third direction;
the first pixel row includes a plurality of sub-pixels of the second color arranged in the second direction;
the second pixel row includes a plurality of sub-pixels of the first color arranged in the second direction;
the third pixel row includes a plurality of sub-pixels of the third color arranged in the second direction;
the first insulation portion is located between two adjacent pixel row groups;
in the third direction, the first insulation portion is located between adjacent pixel openings corresponding to two sub-pixels of the first color;
the orthographic projection of the pixel opening corresponding to the sub-pixel of the first color on the first substrate is the first polygon; and
the first sub-edge of the first polygon and the second sub-edge of the first insulation portion all extend along the second direction.

16. The display panel according to claim 15, wherein:
a contour shape of the orthographic projection of the first insulation portion on the first substrate is same as a contour shape of the orthographic projection of the pixel opening corresponding to the sub-pixel of the second color or the sub-pixel of the third color on the substrate;
the pixel openings corresponding to the sub-pixel of the second color and the first insulation portion include edges parallel to each other and extending in the second direction; and
the first insulation portion and the pixel opening corresponding to the sub-pixel of the third color have edges parallel to each other and extending in the second direction.

17. The display panel according to claim 1, wherein:
in the first direction, the first insulation portion covers the pixel opening.

18. The display panel according to claim 1, wherein:
the second base substrate further includes a touch layer, wherein the touch layer is located between the second substrate and the first insulation layer, the touch layer includes touch electrodes, and in the first direction, the touch electrodes do not overlap with the pixel openings and do not overlap with the first insulation portion; and
the first insulation layer further includes a second insulation portion, wherein the second insulation portion located between adjacent first insulation portions and arranged continuously with the first insulation portions, and in the first direction, the second insulation portion covers the touch electrode and the pixel opening.

19. The display panel according to claim 1, wherein:
the orthographic projection of the first insulation portion on the first substrate is a first circle;
a diameter of the first circle is d1; and
d1≥10 μm.

20. A display device, comprising:
a display panel, including:
a first base substrate and a second base substrate oppositely arranged; and
a support pillar disposed between the first base substrate and the second base substrate,
wherein:
the first base substrate includes a first substrate and a plurality of pixel openings disposed on a side of the first substrate facing the second base substrate;
the second base substrate includes a second substrate and a first insulation layer disposed on a side of the second substrate facing the first base substrate;
the first insulation layer includes a first insulation portion;
in a first direction, the first insulation portion overlaps with the support pillar;
the first direction is perpendicular to a plane where the first substrate is located;
the first insulation portion includes a first edge;
an orthographic projection of the first edge on the first substrate is located outside an orthographic projection of the pixel opening on the first substrate;
the orthographic projection of the first edge on the first substrate and the orthographic projection of the pixel opening on the first substrate have a first preset distance D; and D>0.
